(19) United States
(12) Patent Application Publication
(10) Pub. No.: US 2008/0130259 A1
(43) Pub. Date: Jun. 5, 2008

(54) Shielding Device In A Base Station

(75) Inventor: Johnny Hederoth, Spanga (SE)

Correspondence Address: ALBIHNS STOCKHOLM AB, BOX 5581, LINNEGATAN 2, SE-114 85 STOCKHOLM; SWEDENn, STOCKHOLM, omitted

(73) Assignee: ANDREW CORPORATION, Orlando Park, IL (US)

(21) Appl. No.: 11/571,619

(22) PCT Filed: Jul. 5, 2005
(86) PCT No.: PCT/SE05/01106

§ 371 Date: Jan. 8, 2008

Related U.S. Application Data
(60) Provisional application No. 60/521,832, filed on Jul. 8, 2004.

(30) Foreign Application Priority Data
Jul. 8, 2004 (SE) 0401800-8

(51) Int. Cl. H05K 9/00

(52) U.S. Cl. 361/816

(57) ABSTRACT

Device for shielding components on a printed circuit board (1206) in a radio base station. The circuit board comprises a first circuit section (1801) and a second circuit section (1802), and a conductive border portion (1207) arranged on the circuit board between said first circuit section and said second circuit section. A conductive shielding cover (1208) is attachable over at least the first circuit section, with a wall (1501) end of the cover connected to the border portion with an intermediate conductive gasket (1504). The cover comprises a distance element (1806) devised to engage with a distance reception area (1807), dimensioned such that engagement between the distance element and the distance reception area leaves a gap (1808) between the wall end and the border portion defining a maximum obtainable compression for the intermediate conductive gasket.

### FIELD OF THE INVENTION

The present invention relates to a device for shielding sensitive components on a circuit board by enclosing such components in an electromagnetic shield. In particular, the invention relates to a device for shielding sensitive components in a miniaturized base station for use in third generation (3G) mobile telecommunications systems.

### BACKGROUND

From the initial analog systems, such as those defined by the standards AMPS (Advanced Mobile Phone System) and NMT (Nordic Mobile Telephone), the cellular telephone industry has had an enormous development in the world in the past decades. In the past years, the development has been almost exclusively focused on standards for digital solutions for cellular radio network systems, such as D-AMPS (e.g., as specified in EIA/TIA-IS-54-B and IS-136) and GSM (Global System for Mobile Communications), generally referred to as the second generation of mobile communications systems.

Currently, the cellular technology is entering the 3^{rd} generation, also denoted 3G. WCDMA (Wideband Code Division Multiple Access) is by far the most widely adopted 3G air-interface technology in the new IMT-2000 frequency bands. Standardized by 3GPP (Third Generation Partnership Project) and ITU (international Telecommunication Union), WCDMA has gained broad acceptance within the wireless communication industry. By 2005, there is expected to be close to 100 WCDMA networks in operation globally.

From the outset, WCDMA was designed to provide cost-efficient capacity for both modern mobile multimedia applications and traditional mobile voice services. One of the key benefits of the technology is efficient, flexible support for radio bearers, in which network capacity can be freely allocated between voice and data within the same carrier. WCDMA also supports both multiple simultaneous services and multimedia services comprising multiple components with different service quality requirements in terms of throughput, transfer delay, and bit error rate.

In WCDMA, user data is spread over a bandwidth of circa 5 MHz. The wide bandwidth supports high user data rates and also provides performance benefits due to frequency diversity. However, the exact data transmission speed that will be available for the system users is not easily predictable. The actual capacity in the mobile networks is affected by a number of factors, such as weather conditions, how many users currently communicate through a common base station, and, most importantly, the distance between the user mobile terminal and the base station antenna. In the terminology for WCDMA, a radio base station is referred to as a Node B.

A radio base station contains delicate circuitry, some of which needs electromagnetic shielding. This problem has been targeted in the prior art, e.g. by Denzene et al. in US 2001/0004316 A1. That document discloses an electromagnetic shield including at least one entry hole placed in contact with a circuit board, thereby substantially enclosing a compartment. The circuit board may include ground traces that divide the circuit board into sections. An optional electrically conductive gasket may be used between the ground traces and the shield to provide good electrical contact between the shield and the circuit board. The gasket may for instance be provided by gold or copper filled silicone.

### SUMMARY OF THE INVENTION

In order to provide satisfactory sealing of an electromagnetic shield, it is important that sufficient compression of the gasket intermediate the shield and the circuit board is obtained. If excessive force is used to bolt the shield to the circuit board, the gasket may be damaged leading to a radio leakage. On the other hand, if the shield is not bolted with sufficient force to the circuit board, rigidity is lost in the assembly, which also may lead to loosening of the shield and subsequent radio leakage. A general object of the invention is therefore to provide a solution to the problems related to electromagnetic shielding in radio base stations, using intermediate conductive gaskets.

According to the invention, these objects are fulfilled by a device for shielding components on a printed circuit board in a radio base station, which circuit board comprises a first circuit section and a second circuit section, and a conductive border portion arranged on said circuit board between said first circuit section and said second circuit section. The device comprises a conductive shielding cover attachable over at least said first circuit section, with a wall end of said cover connected to said border portion with an intermediate conductive gasket. Furthermore, said cover comprises a distance element devised to engage with a distance reception area, dimensioned such that engagement between the distance element and the distance reception area leaves a gap between the wall end and the border portion defining a maximum obtainable compression for the intermediate conductive gasket.

In one embodiment, said distance reception area is arranged on said circuit board.

In one embodiment, said distance reception area is flush with said border portion, and said distance element projects a distance corresponding to said gap, from a plane defined by said wall end.

In one embodiment, said distance reception area is arranged on a support member for said circuit board.

In one embodiment, said device comprises fastening means for attaching the cover to the circuit board, wherein said fastening means extend at least partly through said distance element and said distance reception area.

In one embodiment, said gap has a width in the range of 0.1-2 mm.

In one embodiment, said cover comprises a plurality of walls defining at least two shielding compartments.

In one embodiment, said gasket is formed by a string of a flexible conductive compound disposed on said wall end.

### BRIEF DESCRIPTION OF THE DRAWINGS

The features and advantages of the present invention will be more apparent from the following description of the preferred embodiments with reference to the accompanying drawings, on which

FIG. 1 schematically illustrates the network architecture of a RAN (Radio Access Network) according to an embodiment of the invention;

FIG. 2 schematically illustrates the modular concept of a base station devised according to an embodiment of the invention;

FIGS. 3A and 3B schematically illustrate a support unit of the base station according to an embodiment of the invention, disassembled and assembled;

FIG. 4 schematically illustrates the different physical modular components of a base station devised according to FIG. 2;

FIG. 5 schematically illustrates the assembled base station devised according to FIG. 4;

FIG. 6 schematically illustrates the support unit of FIGS. 3A and 3B from a side view;

FIG. 7 schematically illustrates a base station unit according to an embodiment of the invention, from a side view;

FIG. 8 schematically illustrates a first step of attaching the base station unit of FIG. 7 to the support unit of FIG. 6;

FIG. 9 schematically illustrates a second step of attaching the base station unit to the support unit;

FIG. 10 schematically illustrates a functional block overview of a base station according to an embodiment of the invention;

FIG. 11 schematically illustrates an interface of a base station according to an embodiment of the invention;

FIG. 12 schematically illustrates assembly of a base station unit according to a preferred embodiment of the invention;

FIG. 13 schematically illustrates a circuit board for a base station unit according to a preferred embodiment of the invention;

FIG. 14 schematically illustrates the functional layout for the circuit board of FIG. 13;

FIG. 15 schematically illustrates a front cover devised to be attached towards a circuit board as illustrated in FIG. 13;

FIG. 16 schematically illustrates the assembled base station unit of FIG. 12, as seen from below;

FIG. 17 schematically illustrates a design of a wall for a shielding cover for a circuit board portion; and

FIG. 18 schematically illustrates a side view of a device for shielding components on the circuit board, when disassembled, according to an embodiment of the invention;

FIG. 19 schematically illustrates the device of FIG. 18 when assembled;

FIG. 20 schematically illustrates a side view of a device for shielding components on the circuit board, when disassembled, according to another embodiment of the invention; and

FIG. 21 schematically illustrates the device of FIG. 20 when assembled.

### DETAILED DESCRIPTION OF PREFERRED EMBODIMENTS

An embodiment of the present invention relates to a base station for a telecommunications network, intended for use in indoor environment to enhance coverage and increase capacity.

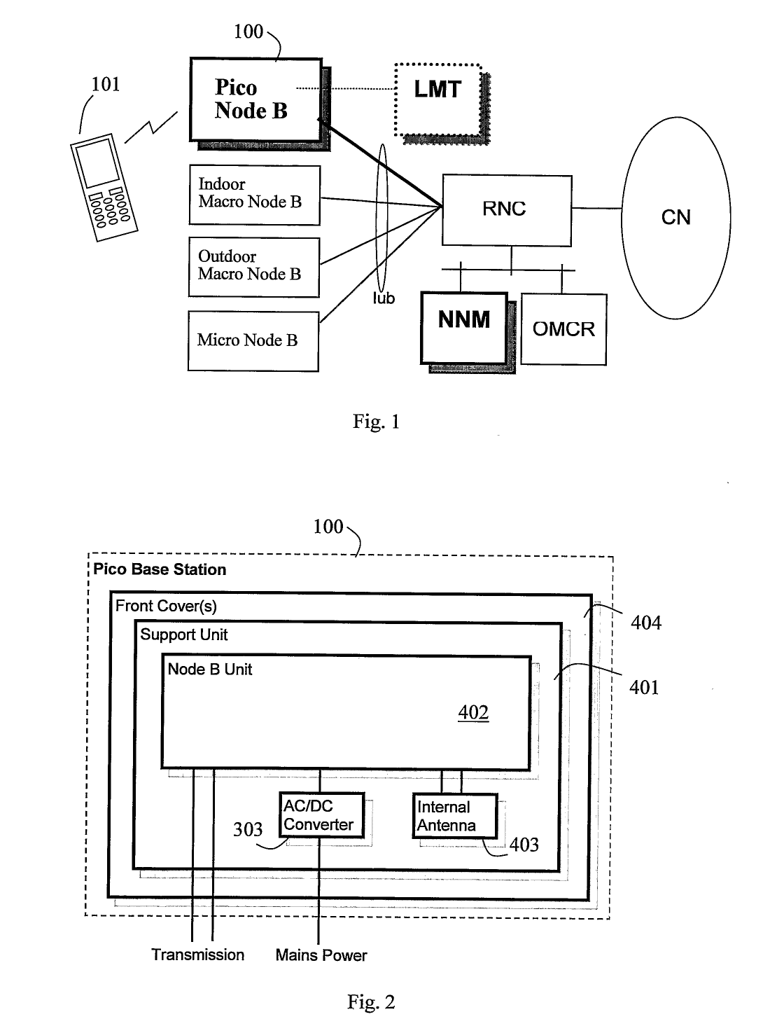

FIG. 1 illustrates the RAN (Radio Access Network) of a telecommunications system in which a base station 100, also referred to as Pico Node B 100, according to the present invention is included. As is indicated to the left in the drawing, the Pico Node B 100 is devised to act as one of a plurality of radio base stations, Node B's, in a common network. Such a plurality of base stations may include indoor macro Node B's, outdoor macro Node B's, and micro Node B's. The Node B's, including base station 100, are devised for radio communication with radio communication terminals 101. The Node B's are connected to an RNC (Radio Network Controller) over an interface Iub, which is the Node B-RNC interface according to 3GPP. The RNC is in turn connected to the CR (Core Network). An LMT (Local Management Tool) may also be coupled to the Pico Node B 100. An NNM (Node B Network Manager) is remotely connectable to the Pico Node B 100 through the RNC, and provides operation and maintenance functions like supervision, software upgrade and alarm handling. Extensive internal hardware and software supervision is part of the Pico Node B 100 functionality. Remotely ordered self-test capabilities are also included.

According to the invention, the Pico Node B 100 is a complete 3GPP/FDD Node B. The Pico Node B 100 supports one carrier and one sector with soft handover together with other Node B's in the radio network. The Pico Node B 100 is optimized for indoor use and is designed accordingly, i.e. low power and high capacity, to be able to serve a large number of indoor users within a limited coverage area. As stated the Pico Node B 100 connects to the RAN, such as UTRAN (UMTS Terrestrial Radio Access Network), system using the Iub interface. Receiver diversity is used together with either an internal antenna or external antennas. The Pico Node B 100 includes duplex filter, and no external duplex filters are needed when using external antennas.

FIG. 2 illustrates the modular concept of the base station, the Pico Node B 100, according to the present invention. In the modular concept of the Pico Node B 100 a Node B Unit (NBU) 402 is the main building block. A support unit 401 serves as a mounting frame for the NBU 402 and different standards of power supply. The support unit can also be customized to house other external units. An internal antenna is optionally included in the concept in order to provide a discrete site installation, and is attachable and electrically connectable directly to the NBU 402. When instead configured with external antennas, a wide variety of antenna types can be connected. The antenna choice is depending on the specific installation environment. Simple directional or omni-directional standard antennas are typically used. Distributed Antenna Systems can also be used together with the Pico Node B 100.

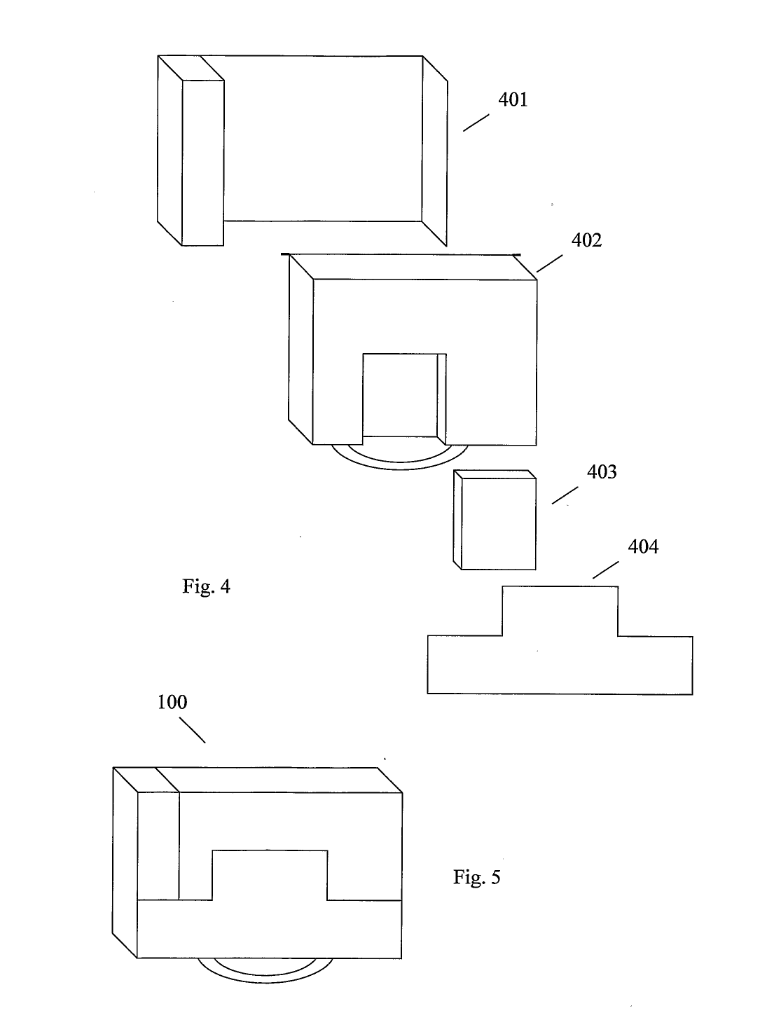

FIG. 4 illustrates the modular components of an exemplary embodiment of the Pico Node B 100. In this standard configuration the Pico Node B 100 comprise a Node B Unit 402, an internal antenna 403, a support unit 401 including a power supply unit 303 with an AC/DC converter and internal cables, and a main cover 404. In FIG. 5 the Pico Node B 100 has been assembled into a complete base station. Preferred embodiments of the assembly and installation procedure is described further down.

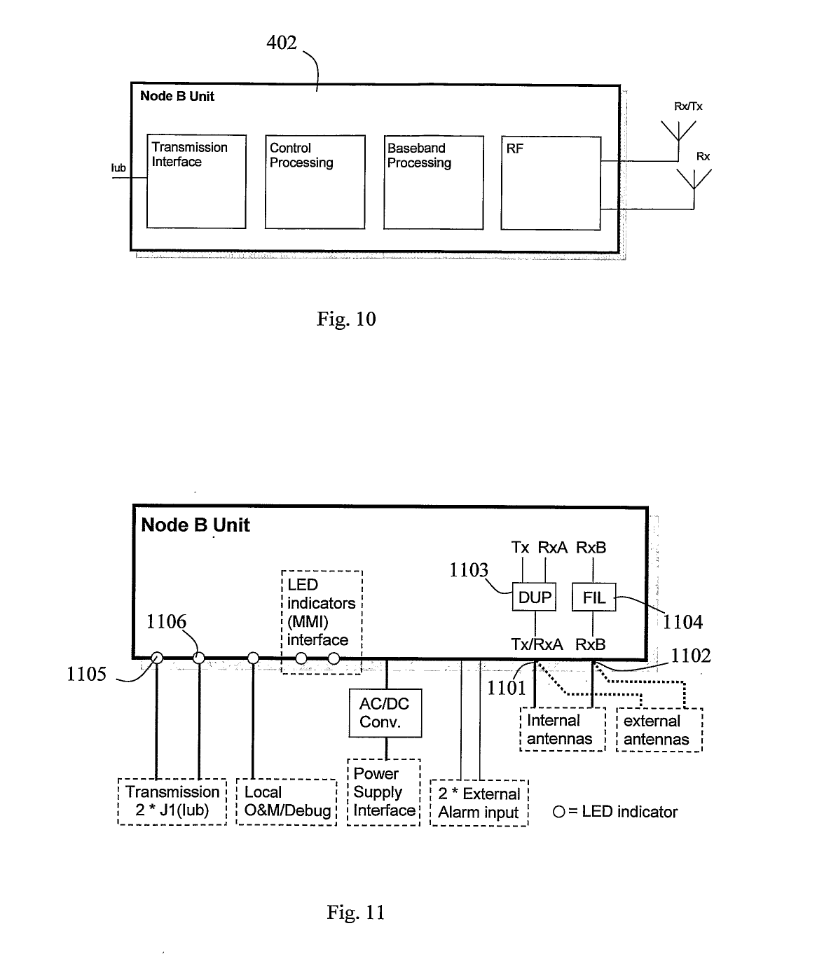

The Node B Unit 402 has a complete 3GPP/FDD (Frequency Division Duplex) Node B functionality with all function blocks in one single hardware unit. A function block overview of the Node B Unit 402 is illustrated in FIG. 10. A preferred embodiment of the Node B Unit 402 comprises the following functional elements:

Transmission Interface Block.
This block handles the physical layer and ATM (Asynchronous Transfer Mode), IP (Internet Packet) and UMTS protocols and the Iub interface to RNC.

Control Processing Block.
This block handles the NBAP (Node B Application Part protocol), O&M functions, call control and clock reference synchronization.

Base Band Processing Block.
This block handles transport channels, physical channels and air interface (layer 1).

RF Block.
This block handles the TRX functionality, i.e. channel filters, AD and DA conversion, TX and RX frequency conversion, transmit power amplifier and receiver low noise amplifier and RF filtering.

The Pico Node B 100 has been intentionally designed for simple and fast installation. Returning to FIG. 4, a complete Pico Node B 100 site installation comprises a support unit 401 (including AC/DC and support cover); a Node B Unit (NBU) 402; an internal antenna 403 (optional); and a main cover 404. Furthermore, transmission and power cables have to be included, but are not shown in FIG. 4.

The first part of the Pico Node B 100 site installation is the mechanical mounting and connection of external cables, and this part mainly involves the support unit. The Node B Unit 402 can be brought to site at a later stage, e.g. at commissioning of the Pico Node B 100. The support unit, including an AC/DC unit, is mounted on the location chosen. Standard installation is wall mounting. However, installation kits for ceiling and pole mounting are also possible. Complete installation requires a power cable 100VAC, and transmission cables, preferably one or two twisted-pair cables with RJ45 connectors, depending on capacity need. If external antennas are used, RF cables with SMA connectors may also be included.

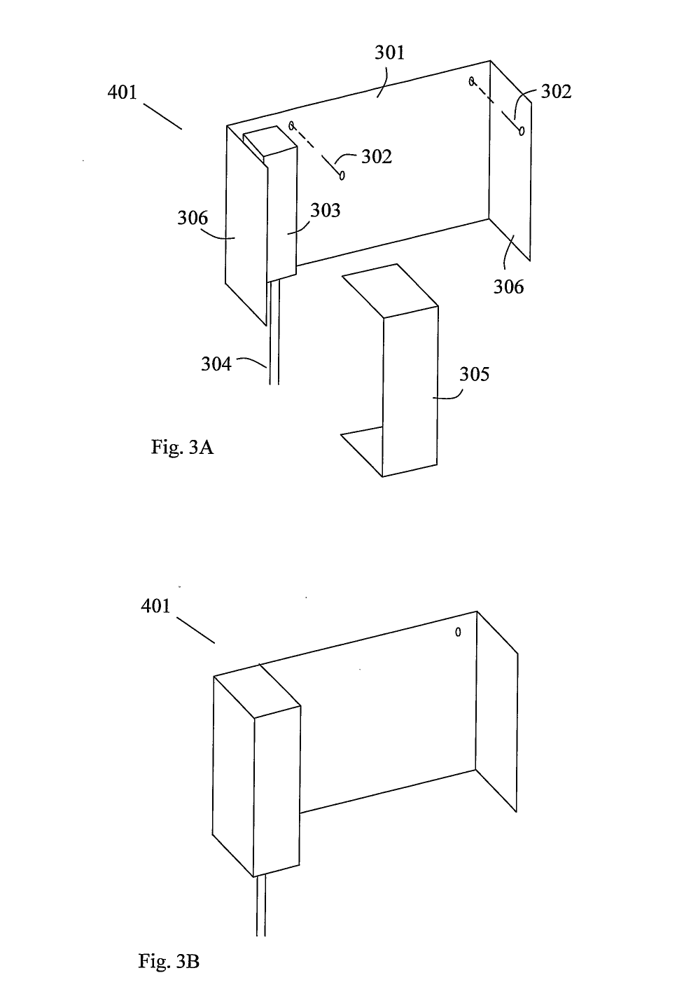

FIGS. 3A and 3B illustrate the support unit 401, which will serve as a mounting frame for the Node B Unit 402, as well as the housing of external units such as the AC/DC converter. A preferred embodiment of the Pico Node B 100 according to the present invention makes use of a supply voltage of AC 100-240 V+/−10% 50/60 Hz, and has a maximum power consumption of <100 W. The standard support unit 401 is used for vertical wall installation, and comprises a plate member 301 having a flat main portion devised to be fitted against a wall e.g. by means of screws 302, bolts, nails or the like. The plate member 301 further includes side wall members 306, extending perpendicular from main portion, as illustrated. AC/DC converter 303 is attached to the main plate member 301, adjacent to a side wall member 306. Power cables 304, which do not form part of the support unit 401 as such, are connected to converter 303 from below. In one embodiment, an additional side wall member may be included, defining a second side wall for a compartment for AC/DC unit 303 of the support unit 401. A support cover 305 is preferably an aluminium part that is used to cover the power supply 303. FIG. 3B illustrates support unit 401 when assembled with its cover 305. The external power line is connected to the AC/DC unit in the support unit. This may either be a fixed installation or be connected using a cable with a plug connected to a wall outlet.

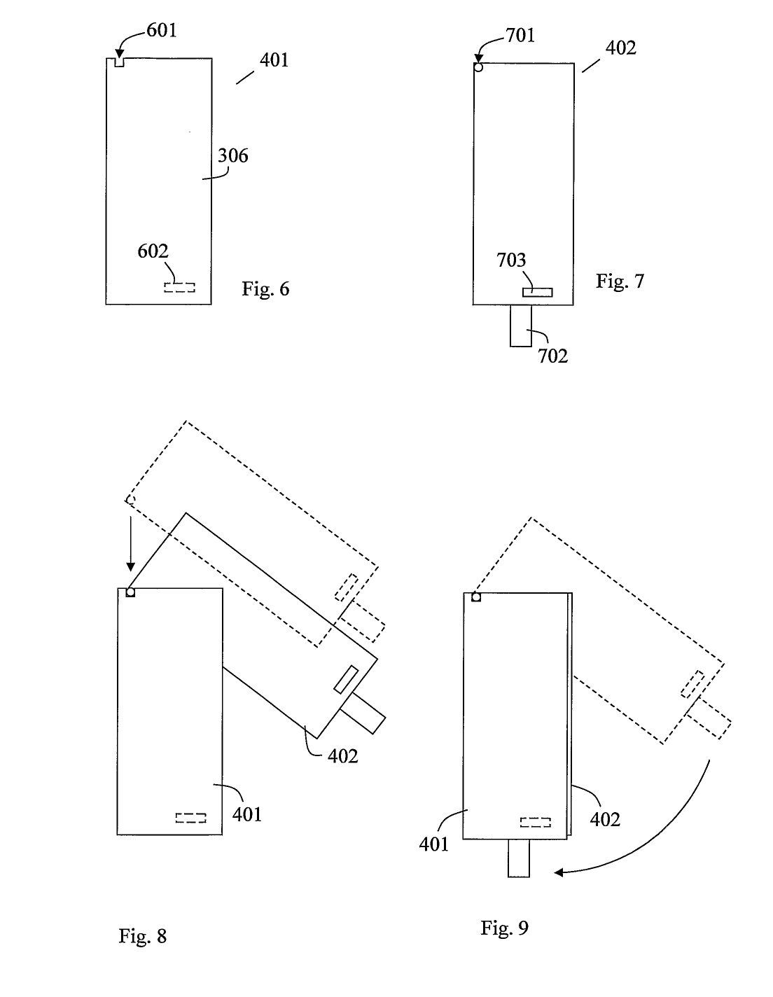

Mounting of the Node B unit (NBU) 402 to support unit 401 is preferably performed as illustrated in FIGS. 6 to 9. The support unit 401 is shown in a side view in FIG. 6, and comprises hanger means at an upper portion of the support unit, e.g. in the form of recessed portions 601 formed in side wall members 306, which recesses are open from above. The NBU 402 is shown in a side view in FIG. 7, in which it is shown that an upper portion of NBU 402 comprises cooperating hanger means 701, preferably in the form of sideways projecting pins 701, see also FIG. 4. The NBU 402 is designed to first be engaged with support unit 401 by placing projecting pins 701 at rest in recesses 601, while holding NBU 402 at an angle to support unit 401, as is illustrated in FIG. 8. For this purpose, a handle 702, which is also illustrated in FIG. 4, is particularly advantageous. NBU 402 is then pivoted about a rotation axis defined by pins 701, until latch means 602 on support unit 401 snaps into engagement with cooperating latch means 703 on NBU 402, as is illustrated in FIG. 9. In one embodiment, those latch means are available from the outer side of side wall members 306 of the support unit 401. In another embodiment a special tool is needed to unlatch the NBU 402 from support unit 401 in order to prevent stealing or tampering. It should be apparent that the described type of hanger means are purely exemplary. An alternative embodiment comprises backwards projecting hooks on the NBU 402, devised to be hung on edges or pins on the upper part of support unit 401. A pivoting function will be achieved with such a solution also.

An internal antenna 403 may be mounted directly on the NBU 402, preferably mechanically attached be means of screws. A transmission cable or cables are preferably installed for connecting the antenna 403 to the NBU 402 antenna connectors 1101, 1102, see FIG. 11. If instead an external antenna is used, the external antenna or antennas and coaxial cables are installed, where said coaxial cables are terminated with SMA connectors connected directly to the Node B Unit 402 at 1101, 1102. Finally cover 404 is mounted. The first part, i.e. mechanical site installation, is then finalized.

The Node B Unit 402 preferably has an external interface according to FIG. 11. With reference to that drawing, one embodiment of the NBU interface comprises:
A transmission interface (Iub), which in this particular case is 2*J1 (IMA) over a twisted pair cable and using ATM as transmission protocol. There is also transmission connection LED indication (yellow) for each transmission line. Cable connectors 1105 and 1106 are included for connection to the network.
An antenna (RF) interface, which has two antenna ports 1101, 1102, for RxA/Tx and RxB, respectively. A duplex filter 1103 and a band pass filter 1104 are included in Node B Unit 402. RxA and RxB are receive diversity branch A respective receive diversity B.
A power supply interface. This interface is internal in Node B with a fixed connection to AC/DC converter depending on used site configuration. The internal Node B Unit 402 input is +12 V DC and the external power supply is 100-240 VAC (input Voltage to the AC/DC).
A Local O&M/Debug interface, which complies with the Ethernet protocol standard. The Local Management Tool (LMT) is connected to this interface. There is also Local O&M connection LED indication (yellow).
A LED Indicator (MMI) Interface, used for Power on LED indication (green) and internal fault status LED indication (red).
An external alarm interface, which supports two external alarm inputs which can be defined and configured by the operator.

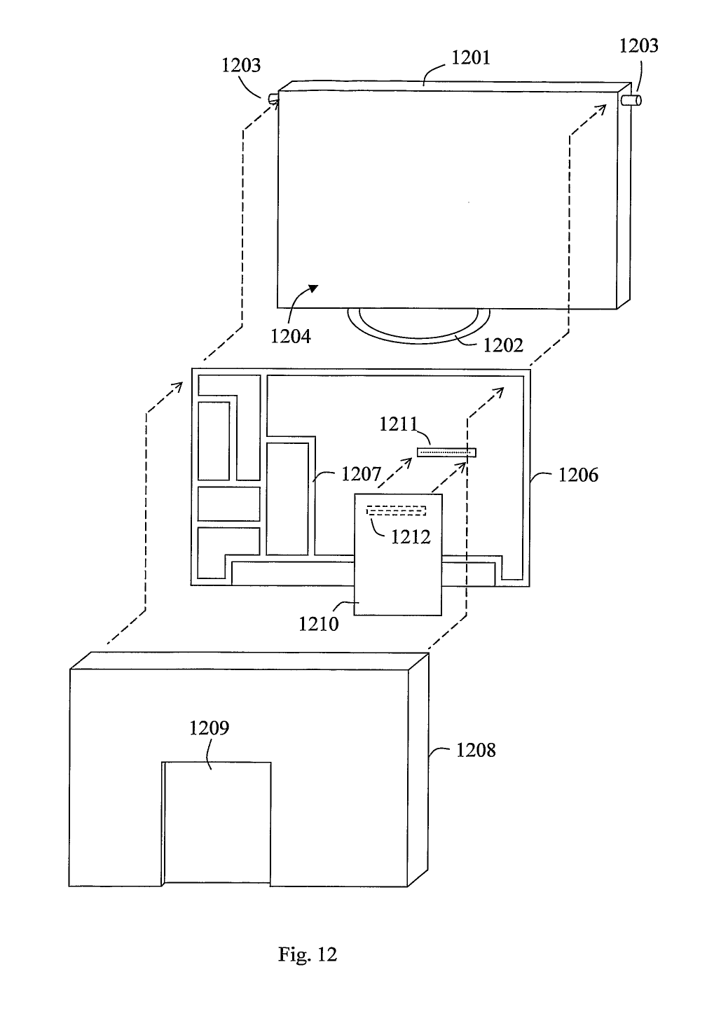

In order to make the Pico Node B 100 as compact and lightweight as possible, special features have been employed in the design of the NBU 402. This is illustrated in FIGS. 12-17.

In FIG. 12, the three main building blocks of the NBU 402 are illustrated. The NBU 402 comprises a back plate 1201, which includes a handle 1202 (corresponding to 702) as an integrated or attached member, and projecting pins 1203 (corresponding to 701). Back plate 1201 is a support member for a circuit board 1206, which is attached to the front side 1204 of back plate 1201, preferably by means of screws, rivets, an adhesive, or the like. Back plate 1201 is preferably made of metal, such as aluminium. The back side 1205 of back plate 1201 is further preferably arranged with cooling flanges, though not shown in FIG. 12. The NBU 402 further includes a front plate 1208, which is attached over circuit board 1206, as indicated in FIG. 12. Front plate 1208 is preferably attached by means of screws to the back plate 1201. Front plate 1208 comprises the mechanical interface 1209 to the optional internal antenna on its front side. In an alternative embodiment, the projecting pins 1203 devised for hanging the NBU 402 on the support plate, may be attached to front plate 1208 instead of the back plate 1201.

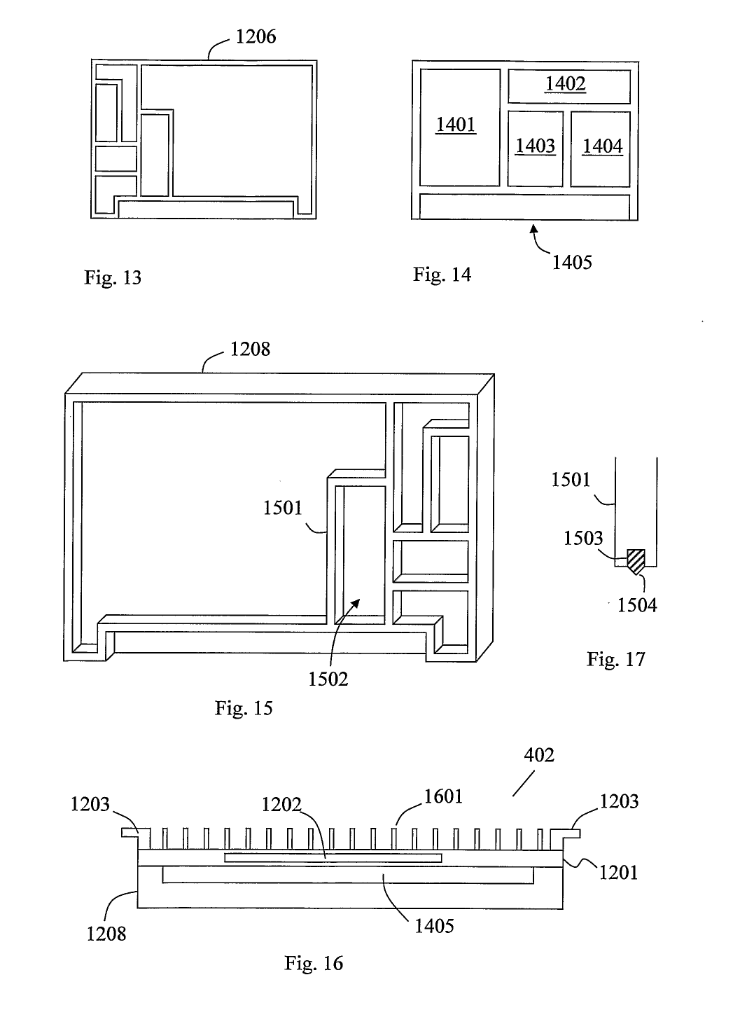

According to this preferred embodiment of the invention, all circuits of the NBU 402 corresponding to the control processing block, the base band processing block and the RF block (cf. FIG. 10) are arranged on one and the same circuit board 1206. On FIGS. 13 and 14, the circuit board 1206 is shown again, in equal scale. FIG. 13 illustrates the physical structure of circuit board 1206, whereas FIG. 14 illustrates the functional layout. With reference to FIG. 10, and the associated description, and to FIG. 14, circuit board 1206 comprises circuitry for the RF block 1401, the base band processing block 1402, and the control processing block 1404. The different functional elements in blocks 1401, 1402 and 1404 are powered through power supply unit 303, which provides a DC voltage. However, different voltage levels are needed for different functional elements, and different levels of accuracy are also required. For this purpose, an internal DC/DC block 1403 is included on circuit board 1206. DC/DC block 1403 is consequently fed by power supply unit 303, and feeds the functional elements of the NBU 402 with electric power at adapted levels of voltage. The circuit board 1206 further carries the interface 1405, i.e. connectors and diodes, indicated in FIG. 11. It should be noted that FIG. 11 is mirror-inverted left to right, compared to interface 1405 of FIG. 14. Interface 1405 is preferably accessible from the lower side of circuit board 1206. As is further illustrated in FIGS. 12 and 13, different parts of the circuitry, in particular different parts of the RF block 1404, are separated from each other by intermediate border portions 1207. These border portions are formed of a conducting material layer, e.g. metal, and are devised to engage with shielding elements as will be explained further down.

In a preferred embodiment, circuitry for the transmission interface block is provided on a separate circuit board 1210, which is attachable to circuit board 1206 as illustrated in FIG. 12. In one embodiment, cooperating piggy back connectors 1211, 1212 on circuit boards 1206 and 1210, respectively, are used for connection. An advantage with having a separate transmission interface circuit board 1210, is that it is easy to adapt the Node B 100 to different transmission connection types to the RNC of the network. In one embodiment, transmission interface circuit board 1210 may be devised for E1 type transmission, and in a different embodiment to J1 transmission. Furthermore, it is possible to provide specific transmission interface circuit boards 1210 for STM-1 type transmission over optical fibre instead of twisted wire, or even for SDSL over ordinary telephone lines. In a preferred embodiment, connectors 1105 and 1106 are carried on the transmission interface circuit board 1210.

Consequently, the inclusion of a separate detachable transmission interface circuit board 1210 provides flexibility to the base station 100, which otherwise may be identical regardless of selected transmission type. This is a clear advantage in terms of manufacture.

According to an embodiment of the invention, the assembly is designed such that cooling of the electronic circuitry is achieved by means of self-convection cooling. The elimination of moving mechanical parts, such as fans, advantageously reduces the risk for component failure due to wear of moving mechanical parts. It also advantageously reduces, or eliminates, the need for condition monitoring and maintenance of moving parts, such as cooling fans having ball bearings that are susceptible to mechanical wear. Hence, the design of the assembly so that cooling is achieved solely by air convection leads to an increased life-time for the base station, and it also reduces the costs for running the base station.

According to a preferred embodiment efficient self-convection cooling is achieved by designing the assembly such that all circuits apart from the transmission interface, are arranged on a single circuit board 1206, which is attached directly to back plate 1201, which back plate is provided with cooling flanges. The self-convection cooling advantageously makes the device noise free, due to the lack of any moving elements, such as cooling fans.

FIG. 15 illustrates front plate 1208 from its back side, devised to face circuit board 1206. As is evident from this drawing, front plate 1208 comprises a pattern of separating walls 1501 on its back side, defining different separate compartments 1502, which pattern corresponds to the border portions 1207 of circuit board 1206. Preferably the entire front plate 1208 is made from a single piece of metal, such as aluminium. When front plate 1208 is attached over the circuit board 1206, the outer end portions of separating walls 1501 engage border portions 1207, thereby electrically enclosing the circuits arranged in the different compartments 1502. At the same time, dividing walls 1501 serve as support means for a mechanically rigid attachment towards the relatively large circuit board 1206, which ensures a secure assembly. In a preferred embodiment, though not specifically shown in the drawings, the outer side walls of front plate 1208 extend over the side edges of circuit board when the NBU 402 is assembled, either fully or at least a lip portion of the side walls, in order to fully enclose the circuit board 1206 in the NBU 402.

FIG. 16 illustrates the assembled NBU 402 as seen from the lower side, in an embodiment of the invention. Back plate 1201 is illustrated with cooling flanges 1601 formed on its back side, i.e. the side which is devised to face the flat main portion of plate member 301 of support unit 401 when the entire Pico Node B 100 base station is assembled. It should be noted that cooling flanges may be formed in front plate 1208 instead, or in both plates 1201 and 1208. Furthermore, handle 1202 is shown, as well as projecting pins 1203. The circuit board 1206 is not visible, as it is enclosed between back plate 1201 and front plate 1208. However, the interface 1405 of the NBU 402, which is also illustrated for an exemplary embodiment in FIG. 10, is accessible for connection to the Iub, the power supply of the support unit, and the antenna, internal or external.

FIG. 17 illustrates a portion of a separating wall 1501, having an end portion directed downwards in the drawing, devised to be placed towards a border portion 1207 according to the previous description. According to an aspect of this embodiment, a notch 1503 may be formed in the end portion of wall 1501, extending all the way along the wall such that a closed loop is formed in the wall end portion around a compartment 1502. A string 1504 of a conductive flexible compound is disposed in the notch, for secure and tight fitting towards the conductive border portions. In an alternative embodiment, end portion of wall 1501 is not provided with any notch, but is instead substantially flat, wherein string 1504 is disposed on said substantially flat end portion of the wall. In both these embodiments, string 1504 at least partly projects from the wall end portion.

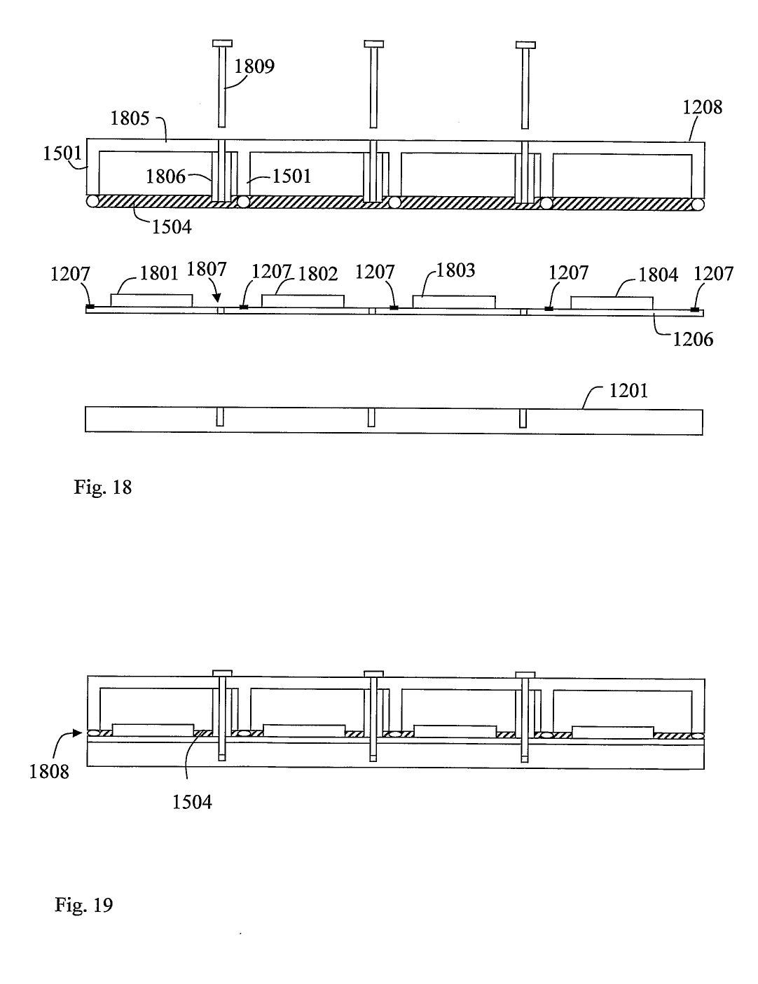

FIGS. 18-19 illustrates one embodiment of a device for shielding components on a printed circuit board in a radio base station, according to the invention. These Figs correspond to what is shown in the drawings of FIGS. 12-16, and like reference numerals are therefore used for like elements. FIG. 18 illustrates a side view of a circuit board 1206 comprising a plurality of circuit sections 1801-1804, including a first circuit section 1801 and a second circuit section 1802. As illustrated in FIGS. 12, 13 and 18, conductive border portions 1207 are arranged on circuit board 1206 between the circuit sections, in particular between the first circuit section 1801 and the second circuit section 1802. Front plate 1208 constitutes a conductive shielding cover, attachable over at least first circuit section 1801, and in the illustrated case over all circuit sections 1801-1804. The shielding cover 1208 includes walls 1501 extending substantially perpendicular to circuit board 1206, and roof portions 1805 connecting said walls. A flexible conductive gasket 1504 is disposed at wall ends of cover 1208. When cover 1208 is attached to circuit board 1206, gasket 1504 is arranged intermediate the ends of walls 1501 and border portions 1207. The gasket may be made of a metal-doped silicone material, a conductive polymer, or e.g. by a compressible material provided by Nolato AB, Sweden, under the trademark trichid.

According to the invention, cover 1208 comprises a distance element 1806 devised to engage with a distance reception area to define a mechanical stop for attachment of cover 1208 to circuit board 1206. In the embodiment of FIGS. 18-19, the distance reception area 1807 is a surface portion of circuit board 1206. The arrangement for shielding components is dimensioned such that engagement between the distance element 1806 and the distance reception area 1807 leaves a gap 1808 between the end of walls 1501 and border portion 1207, defining a maximum obtainable compression for the intermediate conductive gasket 1504. With reference to FIG. 18, this is achieved by protruding distance elements 1806, which extend from cover 1208 a predetermined distance beyond a plane defined by the wall ends of walls 1501. In this embodiment, in which the distance reception area 1807 is arranged on circuit board 1206 and substantially flush with said border portion 1207, distance elements 1806 project a distance corresponding to gap 1808.

FIG. 19 illustrates the same device as FIG. 18, with cover 1206 attached to circuit board 1206. Circuit board 1206 is placed on a support member, provided by means of back plate 1201, and is preferably placed with surface to surface contact on support member 1201. Fastening means for attaching cover 1208 to circuit board 1206 are provided in the form of bolts 1809, which extend from cover 1208 to support member 1201, or alternatively in the opposite direction. Bolts 1809 may be arranged at periphery portions of cover 1208, but in order to obtain optimum attachment the are preferably distributed over the facing surfaces of cover 1208 and circuit board 1206. In the illustrated preferred embodiment, said fastening means 1809 extend at least partly in bores through distance element 1806 and distance reception area 1807, into support member 1201, where attachment is obtained by threaded engagement. It is further clear from FIG. 19 that, when engaged to the point where distance element 1806 connect with distance reception area 1207 to a mechanical stop, gasket 1504 has been compressed to the thickness of gap 1808. By appropriately dimensioning the thickness of gasket 1504, in rested form, and gap 1808, it is ensured that sufficient compression of gasket 1504 is always obtained, and thereby sufficient sealing, with risking to destroy the gasket during assembly.

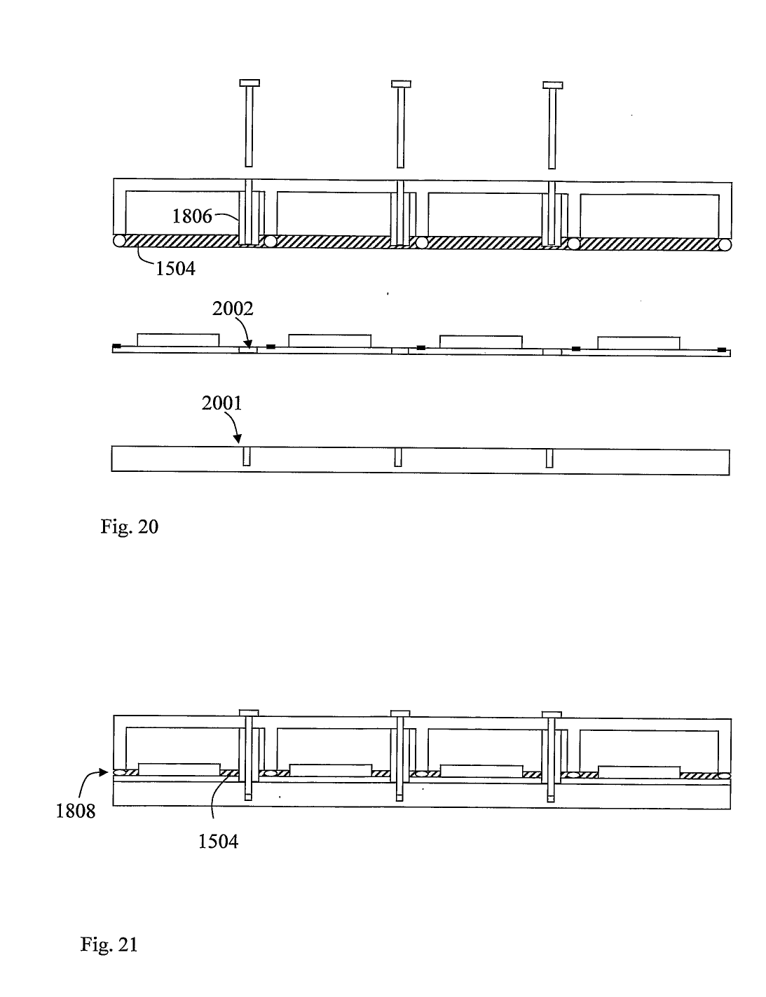

FIGS. 20 and 21 illustrate another embodiment, similar to the embodiment of FIGS. 18-19. However, reference markings are not included for like features already indicated in FIGS. 18 and 19. In the embodiment of FIGS. 20-21, a distance reception area 2001 is defined on support member 1201. A wider bore 2002 is formed in circuit board 1206, into which distance element 1806 is devised to extend upon attachment of cover 1208 to circuit board 1206. In this embodiment, distance elements 1806 project a distance which is larger than gap 1808. In the specific illustrated embodiment of FIGS. 20-21, circuit board 1206 is placed with its back side directly towards the inner surface of support member 1201, on which inner surface distance reception area 2001 is arranged. Therefore, distance element 1806 projects a distance beyond the plane defined by the wall ends of walls 1501, which distance is approximately the width of gap 1808 plus the thickness of circuit board 1206. When engaged, as illustrated in FIG. 21, mechanical stop between distance element 1806 and distance reception area 2001, defines the compressed thickness for gasket 1504 to gap 1808.

In a preferred embodiment, gap 1808 has a width in the range of 0.1-2 mm, and typically 1±0.05 mm. In rested form, gasket 1504 has a thickness which is greater than gap 1808, preferably more than 2 mm. The gasket may be a single separate element, but is preferably formed by a string of a flexible conductive compound disposed on said wall end.

The principles of the present invention have been described in the foregoing by examples of embodiments or modes of operations. However, the invention should not be construed as being limited to the particular embodiments discussed above, and it should be appreciated that variations may be made in those embodiments by persons skilled in the art, without departing from the scope of the present invention as defined by the appended claims.

1. Device for shielding components on a printed circuit board in a radio base station, which circuit board comprises a first circuit section and a second circuit section, and a conductive border portion arranged on said circuit board between said first circuit section and said second circuit section, said device comprising a conductive shielding cover attachable over at least said first circuit section, with a wall end of said cover connected to said border portion with an intermediate conductive gasket, wherein said cover comprises a distance element devised to engage with a distance reception area, dimensioned such that engagement between the distance element and the distance reception area leaves a gap between the wall end and the border portion defining a maximum obtainable compression for the intermediate conductive gasket.

2. The device as recited in claim 1, wherein said distance reception area is arranged on said circuit board.

3. The device as recited in claim 1, wherein said distance reception area is flush with said border portion, and said distance element projects a distance corresponding to said gap, from a plane defined by said wall end.

4. The device as recited in claim 1, wherein said distance reception area is arranged on a support member for said circuit board.

5. The device as recited in, claim 1, comprising fastening means for attaching the cover to the circuit board, wherein said fastening means extend at least partly through said distance element and said distance reception area.

6. The device as recited in claim 1, wherein said gap has a width in the range of 0.1-2 mm.

7. The device as recited in any of the preceding claim 1, wherein said cover comprises a plurality of walls defining at least two shielding compartments.

8. The device as recited in claim 1, wherein said gasket is formed by a string of a flexible conductive compound disposed on said wall end.
